(19) United States
(12) Patent Application Publication
(10) Pub. No.: US 2024/0377856 A1
(43) Pub. Date: Nov. 14, 2024

(54) MULTIFUNCTIONAL COOLING AND SUPPORTING APPARATUS FOR TABLET ELECTRONIC DEVICE

(71) Applicants: Sampson Yang, Irvine, CA (US); Yun-Chang Tsui, New Taipei City (TW); Wei-Chung Wang, Taipei City (TW)

(72) Inventors: Sampson Yang, Irvine, CA (US); Yun-Chang Tsui, New Taipei City (TW); Wei-Chung Wang, Taipei City (TW)

(21) Appl. No.: 18/195,948

(22) Filed: May 11, 2023

(51) Int. Cl. G06F 1/16; G06F 1/20; H05K 5/02; H05K 7/20

(52) U.S. Cl. CPC G06F 1/1628; G06F 1/1656; G06F 1/203; H05K 5/0234; H05K 7/20472

(57) ABSTRACT

A multifunctional cooling and supporting apparatus for a tablet electronic device comprises a protective case including an upper cover and a lower cover assembled to the upper cover; a hollow space formed between the upper cover and the lower cover; the hollow space serving to accommodate the tablet electronic device; the upper cover having an upper opening; the protective case having a waterproof structure which seals the hollow space and prevents external liquid from penetrating the hollow space; and wherein the upper cover is installed with a heat conducting plate which closes and seals the upper opening of the upper cover; the heat conducting plate has a thermal conductive structure; an outer side of the heat conducting plate is exposed from the upper opening; an inner side of the heat conducting plate serves to contact a back end of the tablet electronic device.

### FIELD OF INVENTION The present invention relates to accessories for a tablet electronic device, and in particular to a multifunctional cooling and supporting apparatus for a tablet electronic device.

### BACKGROUND OF INVENTION

There are many peripheral accessories for tablet electronic devices, wherein the protective case is a commonly used accessory for accommodating the tablet electronic device. In order to achieve better protection, many protective cases have a waterproof structure to prevent external water infiltrate the tablet electronic device. One side of the protective may be additionally installed with a stand for supporting the protective case to stand or be connected to other supporting mechanisms; However, above-mentioned waterproof protective case has a closed structure, it cannot dissipate the heat of the tablet electronic device by means of air convection and only has poor heat dissipation performance. Therefore, the temperature of the tablet electronic device is easy to become higher and reduces the operating performance of the tablet electronic device, and even crashes or damages the tablet electronic device. Furthermore, when the above-mentioned protective case is installed with a stand, the disc body on the stand can only be rotated by means of continuous sliding, which causes the stand easy to loosen and difficult to fix at a specific position and it is easy to shake after long-term use and reduce the lifetime. Therefore, all above defects in the prior art are necessary to be improved.

### SUMMARY OF THE INVENTION

To improve above defects in the prior art, the present invention provides a multifunctional cooling and supporting apparatus for a tablet electronic device, wherein a protective case with waterproof structure is provided with a heat conducting plate which can conduct the heat generated by the tablet computer in the protective case to an outer space so as to prevent the tablet computer from overheating. The protective case is further installed with a stand frame. The disk of the stand frame can be rotated step-by-step to be retained at specific location so as not to be loose. Therefore, the lifetime of the stand frame is prolonged and the stand frame can be used to support or hang the protective case, or connect the protective case to other external frames. The present invention has outstanding performance of waterproof, heat conductivity (passive cooling), protecting and supporting. Therefore, the present invention can be used in various outdoor environments. All above mentioned advantages of the present invention cannot be achieved by any prior art.

To achieve above object, the present invention provides a multifunctional cooling and supporting apparatus for a tablet electronic device comprising: a protective case including an upper cover and a lower cover assembled to the upper cover; a hollow space formed between the upper cover and the lower cover; the hollow space serving to accommodate the tablet electronic device; the upper cover having an upper opening; the protective case having a waterproof structure which seals the hollow space and prevents external liquid from penetrating the hollow space; and wherein the upper cover is installed with a heat conducting plate which closes and seals the upper opening of the upper cover; the heat conducting plate has a thermal conductive structure; an outer side of the heat conducting plate is exposed from the upper opening; an inner side of the heat conducting plate serves to contact a back end of the tablet electronic device and heat generated by the tablet electronic device is conducted to the upper opening through the heat conducting plate and dissipates to an external space of the protective case; the present invention further comprises a stand frame installed on an upper side of the protective case; the stand frame including a seat connected to the upper side of the protective case; and wherein an upper side of the seat is installed with a disk and a fixing shaft; the fixing shaft penetrates through a through hole located at a center of the disk; the disk is rotatable with respect to the fixing shaft; an upper surface of the seat is formed with a plurality of recesses which are below the disk; the plurality of recesses are arranged along a circular path which is around a center of the fixing shaft; the disk is rotatable with respect to the seat by using at least one ball; the at least one ball is installed on a bottom side of the disk;

a lower side of the ball exposes out from the bottom side of the disk and is located within one of the recesses of the disk; the disk is formed with an application unit; and when the disk rotates, the ball is driven by the disk to move to another recess to cause the disk is able of being fixed on various angles.

### BRIEF DESCRIPTION OF THE DRAWINGS

FIG. 1 is an assembly schematic view of the present invention.

FIG. 2 is an assembly schematic view showing a bottom side of the present invention.

FIG. 3 is a schematic cross view along line C-C′ of FIG. 2.

FIG. 4 is an exploded schematic view showing the stand frame and the protective case.

FIG. 5 is an exploded schematic view showing the stand frame, upper cover, lower cover and the tablet computer.

FIG. 6 is an exploded schematic view of the protective case.

FIG. 7 is a schematic view showing a bottom side of FIG. 6.

FIG. 8 is an exploded schematic view showing the upper cover, the heat conducting plate and the lower cover.

FIG. 9 is an assembly schematic view of the stand frame.

FIG. 10 is an exploded schematic view of the stand frame.

FIG. 11 is a schematic cross section view along line A-A′ of FIG. 9.

FIG. 12 is a schematic cross section view along line B-B′ of FIG. 9.

FIG. 13 is an exploded schematic view showing the pivotal unit and insertion unit of the present invention.

FIG. 14 is a schematic view showing the rotation of the disk.

FIG. 15 is a schematic view showing that the stand frame is used to support the protective case.

FIG. 16 is a schematic view showing the application of rotation of the disk and the turning of the rotating frame.

FIG. 17 is a schematic view showing an application which shows that the stand frame is used as a hander.

FIG. 18 is a schematic view showing the application of the hand strap.

FIG. 19 is a schematic view showing that the stand frame is used to connect the supporting object.

FIG. 20 is a schematic view showing the supporting object of FIG. 19.

FIG. 21 is a partial schematic view showing that the supporting object of FIG. 20 is viewed from another viewing angle.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

In the present invention, a tablet computer 1 is used for description of the present invention, however the present invention is suitable for various kinds of tablet (or flat form) electronic devices, such as tablet computers, mobile phones, PDA (personal digital assistant), notebook computers, etc. Preferably, these tablet electronic device has a flat back side.

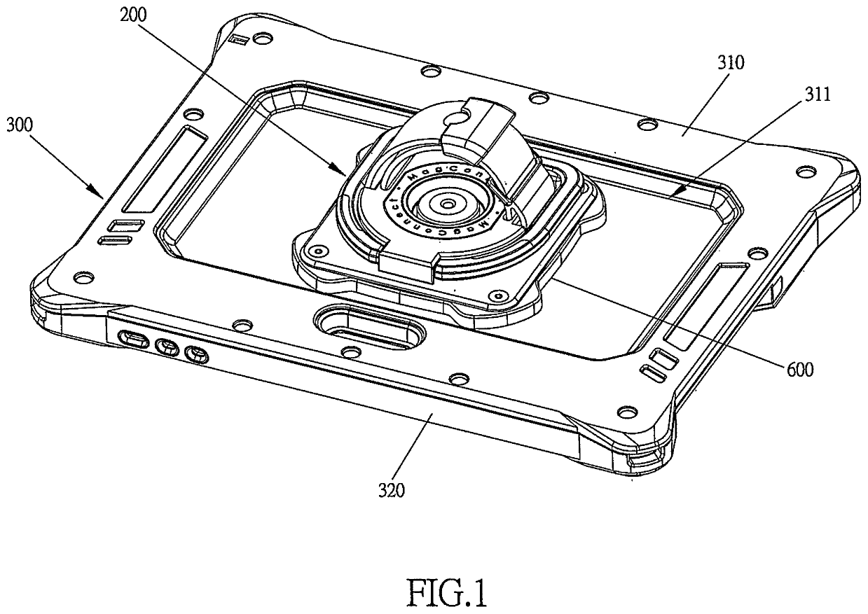

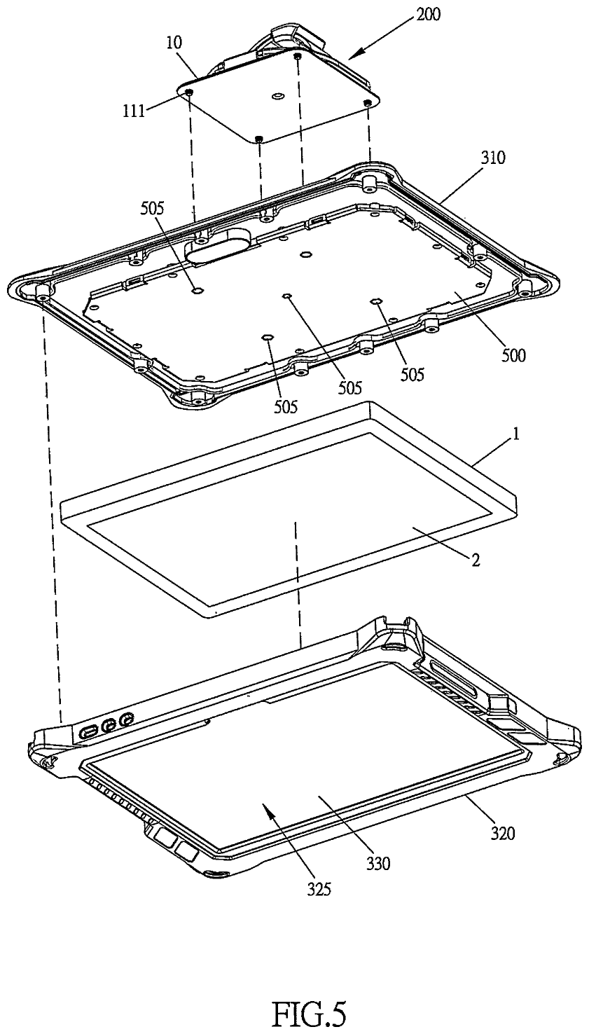

With reference to FIGS. 1 to 21, the structure of the present invention is illustrated. The present invention contains the following elements.

A protective case 300 including an upper cover 310 and a lower cover 320 which is assembled to the upper cover 310, as shown in FIGS. 1, 2, 3 and 5. A hollow space 301 is formed between the upper cover 310 and the lower cover 320. The hollow space 301 serves to accommodate a tablet computer 1. The upper cover 310 has an upper opening 311 and the lower cover 320 has a transparent area 325. A screen 2 of the tablet computer 1 faces the transparent area 325 and a back end of the tablet computer 1 faces the upper opening 311. The upper cover 310 is assembled to the lower cover 320 by means of screwing, buckling, embedding, etc.

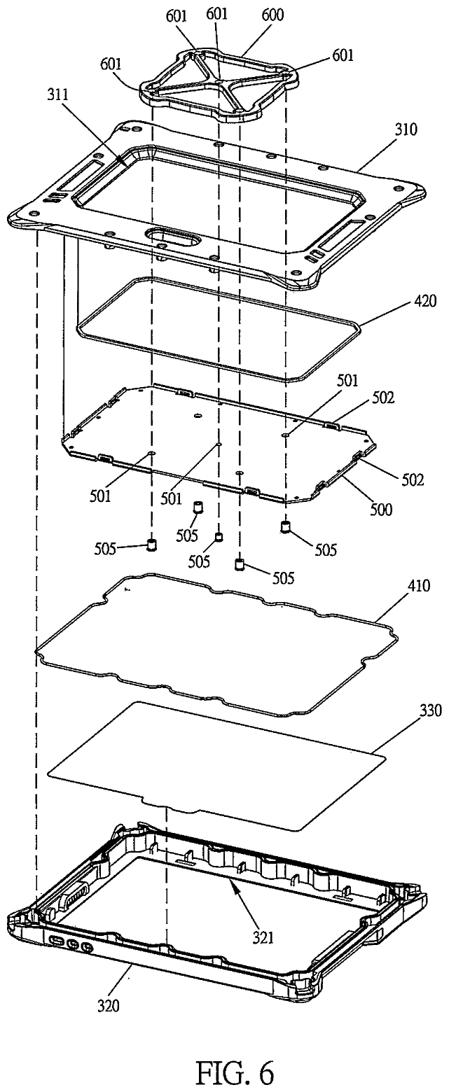

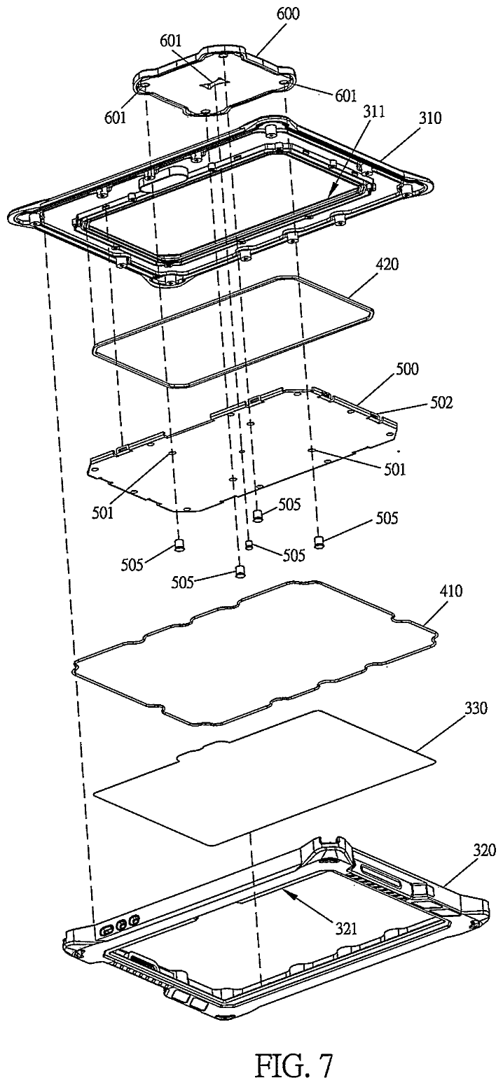

The protective case 300 has a waterproof structure which seals the hollow space 301 and prevents external liquid from penetrating the hollow space 301. Referring to FIGS. 6 and 7, a first waterproof annular strip 410 is installed between an inner side of the upper cover 310 and an inner side of the lower cover 320. The first waterproof annular strip 410 seals the gap between the inner side of the upper cover 310 and the inner side of the lower cover 320. The upper cover 310, the lower cover 320 and the first waterproof annular strip 410 form the waterproof structure of the protective case 300 to seal the hollow space 301 so that external liquid cannot enter into the hollow space 301 through the gap between the inner side of the upper cover 310 and the inner side of the lower cover 320.

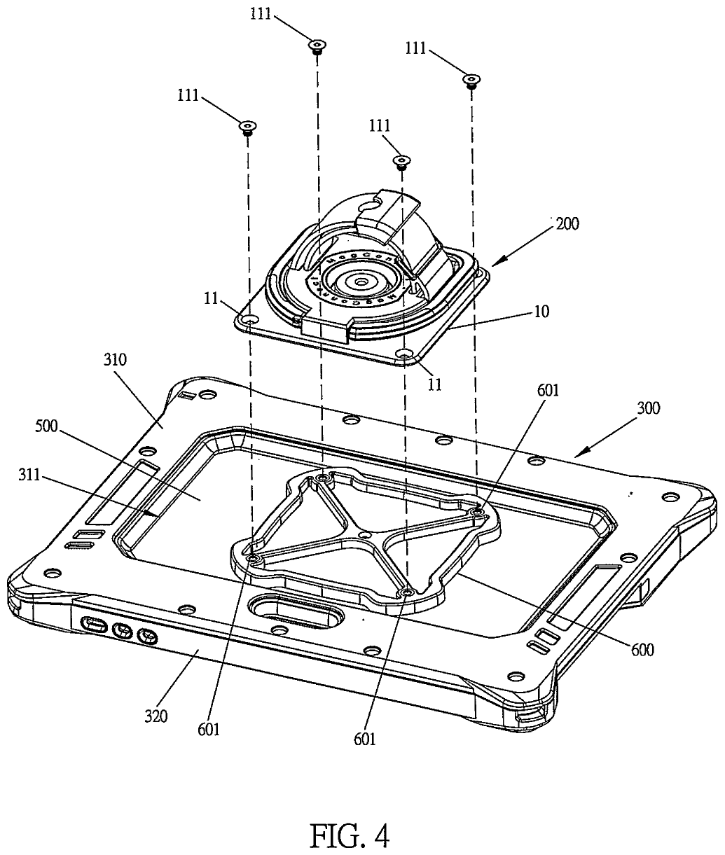

Referring to FIGS. 4 to 8, the upper cover 310 is installed with a heat conducting plate 500 which closes and seals the upper opening 311 of the upper cover 310. The heat conducting plate 500 has a thermal conductive structure. An outer side of the heat conducting plate 500 is exposed from the upper opening 311. An inner side of the heat conducting plate 500 serves to contact the back end of the tablet computer 1 and heat generated by the tablet computer 1 is conducted to the upper opening 311 through the heat conducting plate 500 and dissipates to external space of the protective case 300. Preferably, material of the conducting plate 500 is selected from at least one of metal, thermal conductive polymer, graphite and graphene. The heat conducting plate 500 has a rectangular shape.

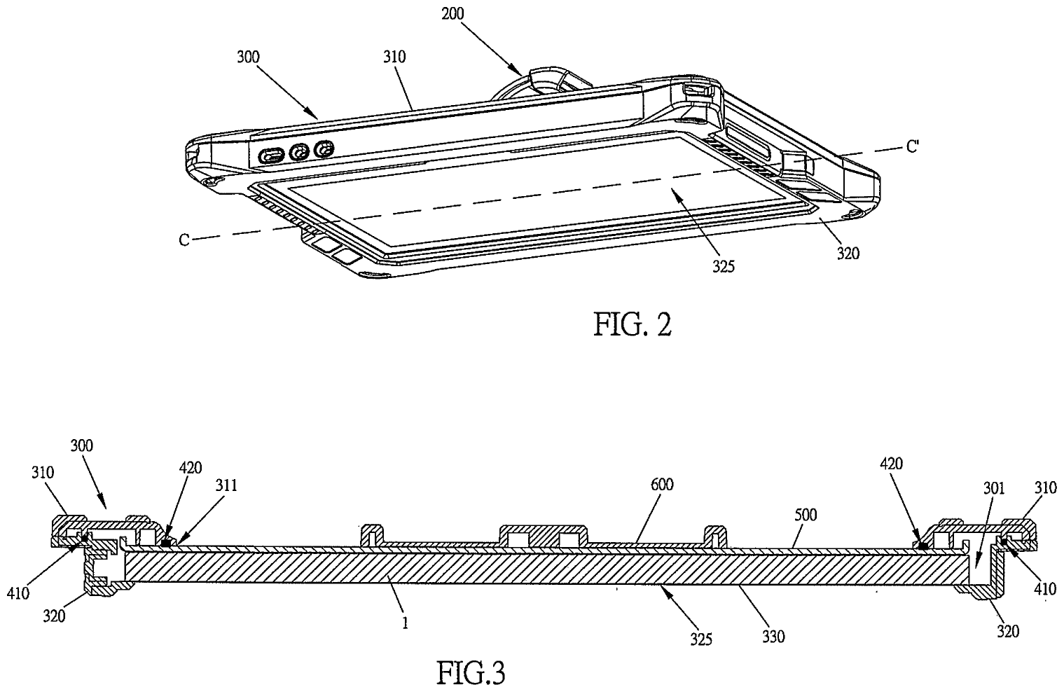

The heat conducting plate 500 is able to seal the upper opening 311 by using various sealing structures. Referring to FIGS. 2, 6 and 7, the heat conducting plate 500 is installed in an inner side of the upper opening 311 by a detachable way and the heat conducting plate 500 seals the upper opening 311 through a second waterproof annular strip 420. The second waterproof annular strip 420 is installed between the heat conducting plate 500 and the inner side of the upper opening 311. The second waterproof annular strip 420 surrounds the inner side of the upper opening 311 and seals a gap between the heat conducting plate 500 and the inner side of the upper opening 311. The inner side of the upper opening 311 has a plurality of first buckles 312 and the heat conducting plate 500 has a plurality of second buckles 502 to buckle the first buckles 312 to fix the heat conducting plate 500 to the inner side of the upper opening 311.

In addition to using above-mentioned second waterproof annular strip 420, the heat conducting plate 500 can also directly seals the upper opening 311 through glue. The inner side of the upper opening 311 has glue to bind the heat conducting plate 500 so that a gap between the heat conducting plate 500 and the inner side of the upper opening 311 is sealed by the glue.

The lower cover 320 of the protective case 300 has a lower opening 321 which is sealed by a transparent plate 330. The transparent plate 330 forms the transparent area 325 of the lower cover 320 to protect the tablet computer 1. User can view the screen 2 of the tablet computer 1 through the transparent plate 330.

Referring to FIGS. 1 and 4, the protective case 300 further includes a connecting base 600 installed on the outer side of the heat conducting plate 500 by a plurality of second connecting components 505 which passes through a plurality of first assembling holes 601 of the connecting base 600 and a plurality of second assembling holes 501 of the heat conducting plate 500.

A stand frame 200 is installed on an upper side of the protective case 300. The stand frame 200 includes following elements.

A seat 10. A bottom of the seat 10 is connected to the upper side of the protective case 300 by a plurality of connecting units 111. The connecting units 111 pass through a plurality of retaining holes 11 of the seat 10 and the first assembling holes 601 of the connecting base 600 (as shown in FIG. 4). Preferably, the seat 10 is a rectangular flat plate 13 and the plurality of retaining holes 11 are at four corners of the flat plate 13.

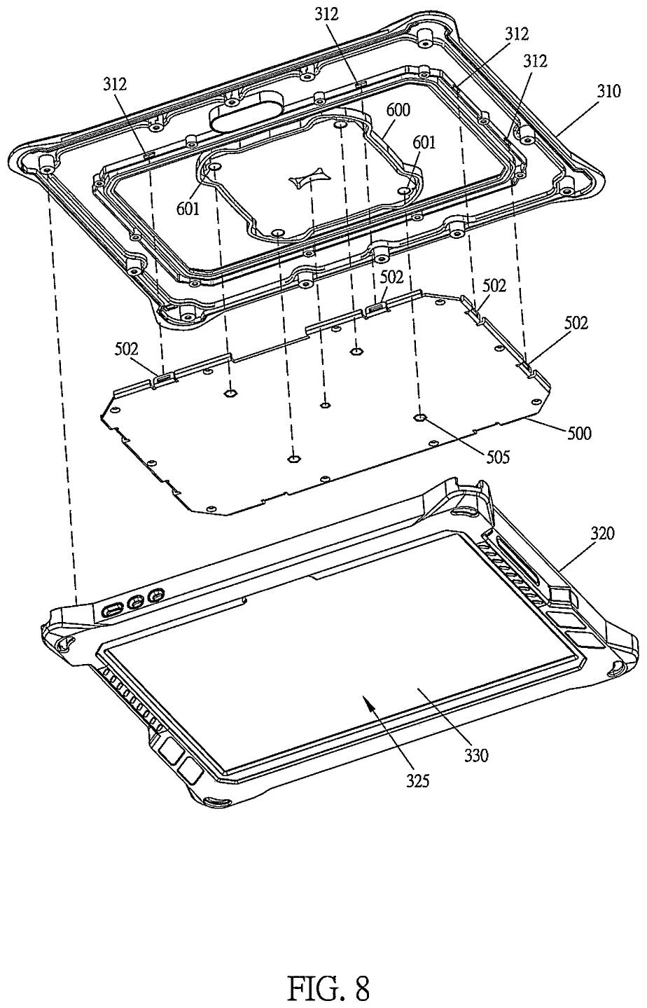

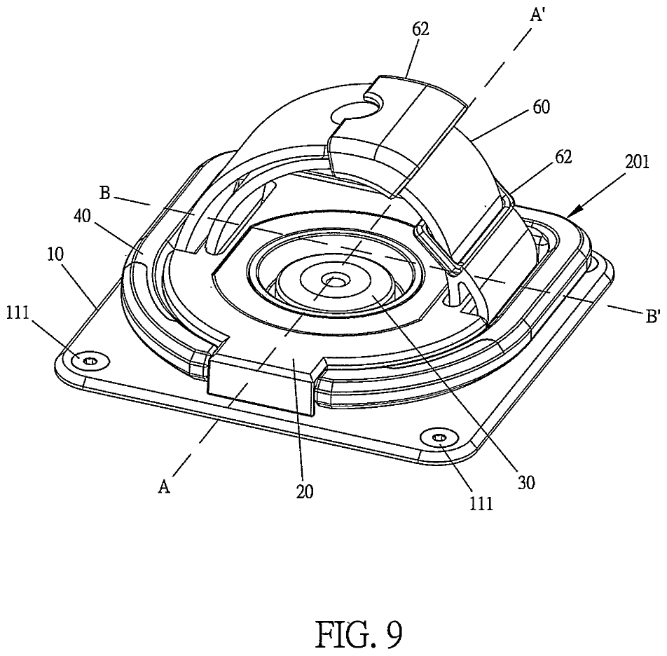

A disk 20 is located above an upper side of the seat 10 and is rotatably installed to the seat 10 (as shown in FIG. 9). A center of the disk 20 has a through hole 21.

A fixing shaft 30 is installed on the seat 10 and penetrates through the through hole 21 of the disk 20. The disk 20 is loosely arranged to the seat 10 through the fixing shaft 30 and is rotatable with respect to the fixing shaft 30.

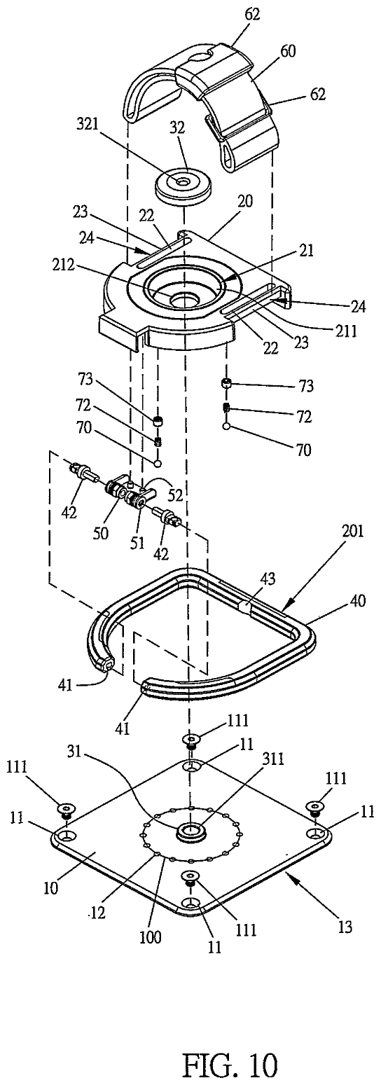

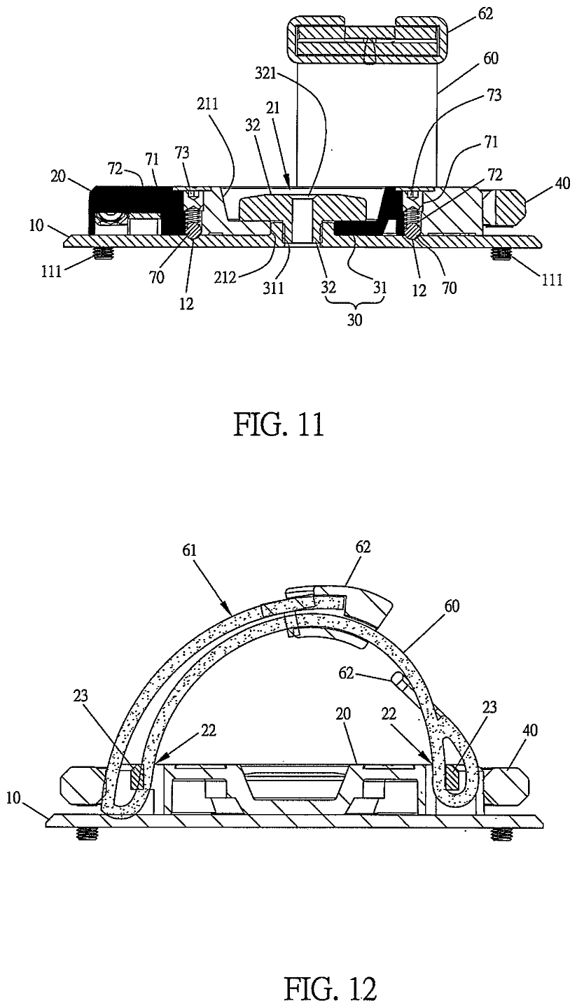

As shown in FIG. 11, the fixing shaft 30 contains a rotatable shaft 31 at a center portion of the seat 10 and a fixing unit 32 connected to an upper side of the rotatable shaft 31. A center of the rotatable shaft 31 is formed with a locking hole 311. An upper side of the fixing unit 32 is formed with an expansion portion 33 and the disk 20 is clamped between the expansion portion 33 and the seat 10. A lower side of the fixing unit 32 is locked to the locking hole 311 of the rotatable shaft 31. Preferably, the rotatable shaft 31 and the seat 10 are integrally formed. The locking hole 311 of the rotatable shaft 31 penetrates through the seat 10.

Preferably, the through hole 21 contains an upper hole 211 and a lower hole 212 at a lower side of the upper hole 211. The cross section of upper hole 211 is larger than that of the lower hole 212. The expansion portion 33 is embedded into the upper hole 211 to resist against a bottom of the upper hole 211.

An upper surface of the seat 10 is formed with a plurality of recesses 12 which are below the disk 20. The plurality of recesses 12 are arranged along a circular path 100 which is around a center of the fixing shaft 30. Preferably, the plurality of recesses 12 are 16 recesses 12 which are arranged around a round and are spaced with an equal distance. Two adjacent recesses 12 have an angle deviation of 22.5 degrees.

The disk 20 is rotatable with respect to the seat 10 by using at least one ball 70. The disk 20 is formed with at least one installing hole 71 which is opened at a bottom side of the disk 20. Each of the at least one installing hole 71 is installed with one of the at least one ball 70. A lower side of the ball 70 exposes out from a lower opening of the installing hole 71 and is located within one of the recesses 12 of the disk 20. An upper side of each of the at least one ball 70 is installed with a respective spring 72 which is confined with the installing hole 71. The ball 70 exposes out of the disk 20 or reduces into the installing hole 71 through elasticity of the spring 72. Preferably, there are two balls 70 embedded into two of the recesses 12 which have angle deviation of 180 degrees.

Preferably, a sealing unit 73 is arranged at an upper side of the installing hole 71 to seal the spring 72 within the installing hole 71. In the drawing the sealing unit 73 is a screw.

By using above said structure, rotation of the disk 20 with respect to the seat 10 cause that the ball 70 moves from one recess 12 to another recess 12 and the disk 20 is rotated step-by-step around an upper side of the seat 10.

The disk 20 is formed with an application unit 201. By the application unit 201, the present invention may be provided with many applications.

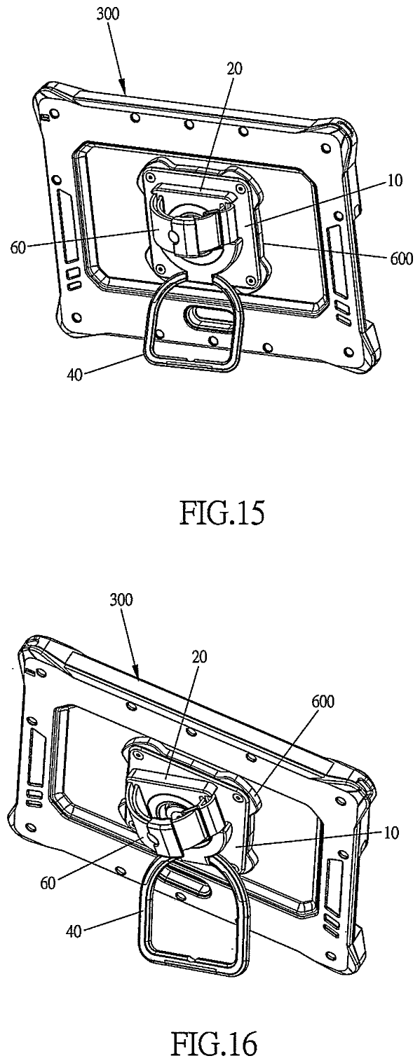

In the present invention, the application unit 201 is a rotating frame 40. One end of the rotating frame 40 is pivotally installed at a side of the disk 20. By rotating the rotating frame 40, the rotating frame 40 serves to support the protective case 300 so as to cause the protective case 300 to stand. As shown in FIG. 15, an angle is formed between the rotating frame 40 and the protective case 300.

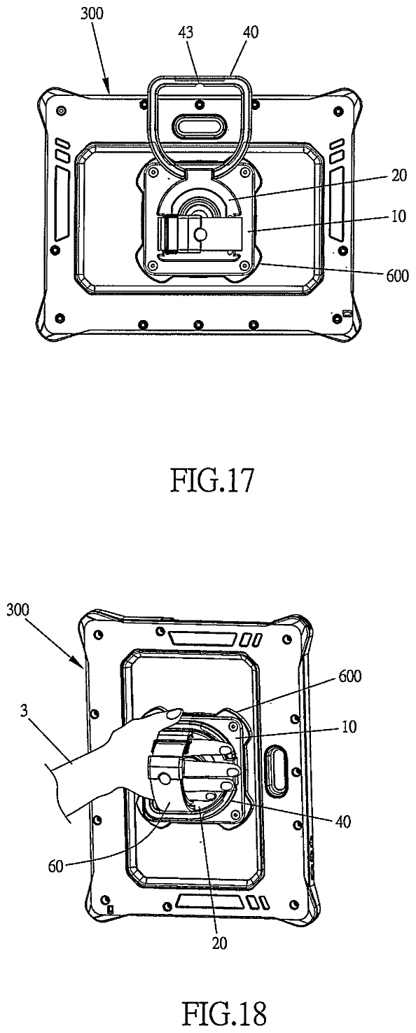

By rotating the rotating frame 40, the rotating frame 40 is also used as a hander. As shown in FIG. 17, when the rotating frame 40 is rotated to be parallel to the seat 10, a side of the frame 40 far away from the disk 20 serves to hang the protective case 300 on a specific location. Preferably, the side of the rotating frame 40 far away from the disk 20 is formed with a groove 43 to receive a fixed end of an external object (not shown).

When the disk 20 rotates, the rotating frame 40 rotates with the disk 20 and the ball 70 leaves from the recess 12 and is pressed by the seat 10 to move into the respective installing hole 71. When the installing hole 71 moves to another recess 12, the ball 70 exposes out from the installing hole 71 again and is embedded into another recess 12 so as to cause the disk 20 and the rotating frame 40 are able of being rotated step-by-step to be fixed on various angles, as shown in FIG. 14. In this embodiment, the angle between two adjacent recesses 12 is 22.5 degree and therefore, when rotating the disk 20 through 22.5 degrees, the disk 20 is retained to another angle.

The side of the disk 20 pivotally installed to the rotating frame 40 has a curve structure. The rotating frame 40 has an approximate circular structure and is fitting to outlines of the disk 20. In a storing state, the rotating frame 40 is annularly arranged an outer periphery of the disk 20.

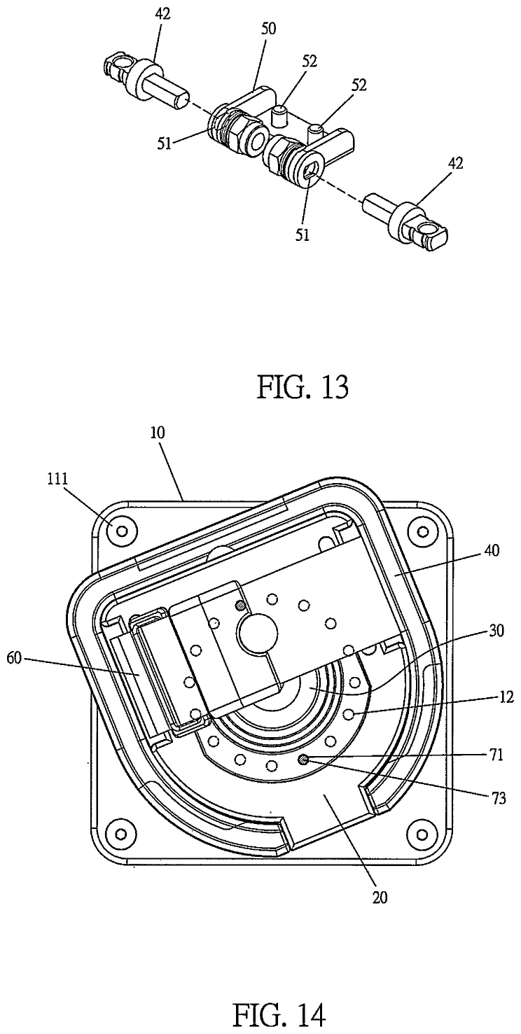

The disk 20 is pivotally installed to the rotating frame 40 by using a pivotal unit 50. The pivotal unit 50 is located at the side of the disk 20. Two ends of the pivotal unit 50 are formed with two respective pivotal holes 51. Two ends of the rotating frame 40 are connected to the pivotal unit 50 by two respective inserting units 42. One end of the inserting unit 42 is installed on a respective connecting hole 41 at one of the two ends of the rotating frame 40. Another end of the inserting unit 42 is inserted into the respective pivotal hole 51 at one of the two ends of the pivotal unit 50 (as shown in FIG. 13) to cause that the rotating frame 40 is rotatable around a center of the inserting unit 42. Preferably, the pivotal unit 50 is locked on the disk 20 by using a screw 52. The two ends of the inserting unit 42 have a cylindrical structure and a middle part of the inserting unit 42 has a larger cross section than those of the two ends of the inserting unit 42.

The stand frame 200 further includes a hand strap 60 which is arranged across two sides of the disk 20 by a detachable way. The two sides of the disk 20 are formed with two via holes 22, respectively. A rib 23 is formed between one of the two via holes 22 and a respective one of the two sides of the disk 20. Totally, there are two ribs 23. Two ends of the hand strap 60 are wound around the respective ribs 23. A middle part of the hand strap 60 is arranged above the disk 20. The middle part of the hand strap 60 has an arc portion 61. The hand strap 60 serves to be held on a user's hand. A space between the hand strap 60 and the disk 20 serves to receive a user's hand 3 so that the hand strap 60 winds around the user's hand 3, as shown in FIG. 18. Therefore, the user can take the protective case 300. The hand strap 60 is installed with at least one buckling ring 62 to hold the hand strap 60.

As shown in FIG. 12, one end of the hand strap 60 passes an outer side of one of the two ribs 23 and passes through the via hole 22 of the respective rib 23 from the bottom of the via hole 22 to a top of the via hole 22 so as to connect to one end of the arc portion 61 of the hand strap 60. Another end of the hand strap 60 passes through another via hole 22 to reach the bottom of the disk 20 and passes from outer side of the respective rib 23 to reach a top of the disk 20 so as to connect to a upper side of the arc portion 61. By adjusting a location of another end of the hand strap 60, a size of the space between the arc portion 61 and the disk 20 is adjustable to suit the user's hand 3.

Preferably, the hand strap 60 is a Velcro. The two ends of the hand strap 60 are adhesive to the arc portion 61 of the hand strap 60.

Preferably, a hollow area 24 is formed between one of the two ribs 23 and a respective outer side of the disk 20. Totally, there are two hollow areas 24. The two ends of the hand strap 60 are embedded into the two hollow areas 24, respectively.

When using, the tablet computer 1 is placed into the protective case 300. The protective case 300 prevents external water from penetrating into the tablet computer 1 and protects the tablet computer 1 from damage. The heat conducting plate 500 conducts the heat generated by the tablet computer 1 to external space of the protective case 300 to ensure that the tablet computer 1 is able to operate in appropriate normal temperature and will not damage or crash due to high temperature. Therefore, the prevent invention can be used in various outdoor environments.

For causing the protective case 300 to stand, the user can rotate the disk 20 to a specific direction to adjust the direction of the rotating frame 40. Then the rotating frame 40 is rotated to cause that the rotating frame 40 supports the protective case 300, and therefore, the protective case 300 and the tablet computer 1 can stand. As shown in FIG. 16, a standing direction and a standing angle of the tablet computer 1 is changeable by adjusting the angle of the disk 20 and the angle between the rotating frame 40 and the protective case 300.

For hanging the protective case 300, the user can rotate the disk 20 to a specific location to change the direction of the rotating frame 40. Then, rotating the rotating frame 40 causes the rotating frame 40 to be hung from a specific location, such as a wall. A hanging angle of the protective case 300 is changeable by adjusting the angle of the disk 20.

If the user desires to take the protective case 300, the user can make his or her hand 3 pass through the space between the arc portion 61 of the hand strap 60 and the disk 20 so that the hand strap 60 winds around the user's hand 3. To take the protective case 300, the user can also directly hold the hand strap 60.

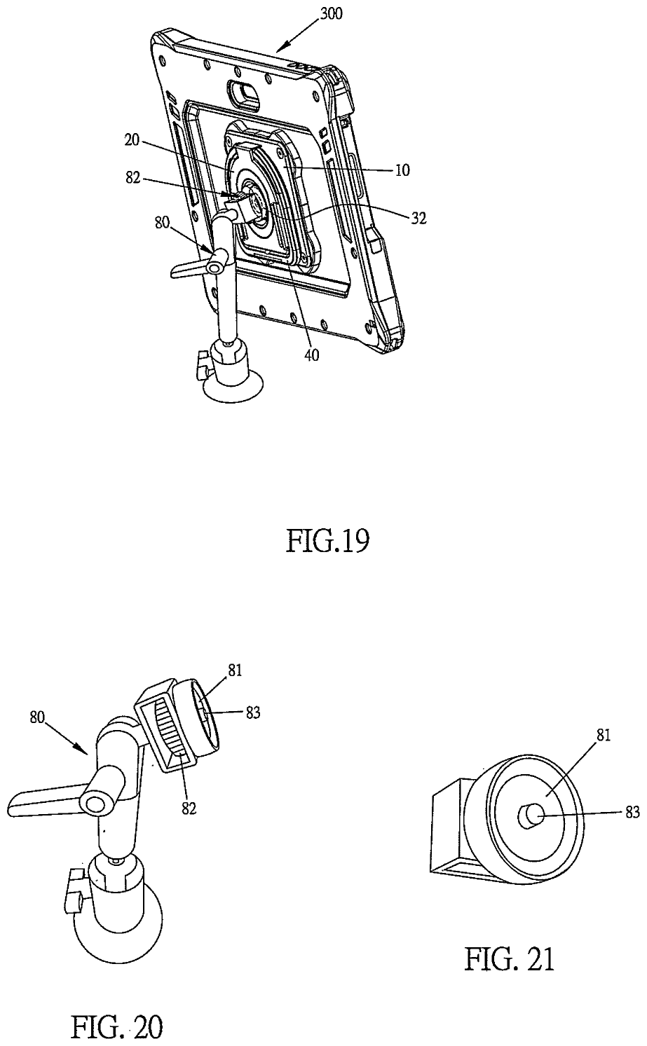

As shown in FIG. 10, a center of the fixing unit 32 has a screw hole 321 for screwing an object. An application example is shown in FIG. 19. The protective case 300 is retained on a supporting object 80. The supporting object 80 is screwed to the screw hole 321 at the center of the fixing unit 32. The supporting object 80 contains a connecting magnetic surface 81 (as shown in FIGS. 20 and 21). A center of the connecting magnetic surface 81 has a screw rob 83 which is movable by using a screw ring 82. By connecting the connecting magnetic surface 81 and the outer surface of the fixing unit 32, and rotating the screw ring 82 to cause the screw rob 83 to screw into the screw hole 321 of the fixing unit 32, so that the supporting object 80 can be installed on the protective case 300 stably.

Advantages of the present invention are that a protective case with waterproof structure is provided with a heat conducting plate which can conduct the heat generated by the tablet computer in the protective case to an outer space so as to prevent the tablet computer from overheating. The protective case is further installed with a stand frame. The disk of the stand frame can be rotated step-by-step to be retained at specific location so as not to be loose. Therefore, the lifetime of the stand frame is prolonged and the stand frame can be used to support or hang the protective case, or connect the protective case to other external frames. The present invention has outstanding performance of waterproof, heat conductivity (passive cooling), protecting and supporting. Therefore, the present invention can be used in various outdoor environments. All above mentioned advantages of the present invention cannot be achieved by any prior art.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A multifunctional cooling and supporting apparatus for a tablet electronic device comprising:
a protective case including an upper cover and a lower cover assembled to the upper cover; a hollow space formed between the upper cover and the lower cover; the hollow space serving to accommodate the tablet electronic device; the upper cover having an upper opening;
the protective case having a waterproof structure which seals the hollow space and prevents external liquid from penetrating the hollow space; and
wherein the upper cover is installed with a heat conducting plate which closes and seals the upper opening of the upper cover; the heat conducting plate has a thermal conductive structure; an outer side of the heat conducting plate is exposed from the upper opening; an inner side of the heat conducting plate serves to contact a back end of the tablet electronic device and heat generated by the tablet electronic device is conducted to the upper opening through the heat conducting plate and dissipates to an external space of the protective case.

2. The multifunctional cooling and supporting apparatus for the tablet electronic device as claimed in claim 1, further comprising:
a stand frame installed on an upper side of the protective case; the stand frame including a seat connected to the upper side of the protective case; and
wherein an upper side of the seat is installed with a disk and a fixing shaft; the fixing shaft penetrates through a through hole located at a center of the disk; the disk is rotatable with respect to the fixing shaft; an upper surface of the seat is formed with a plurality of recesses which are below the disk; the plurality of recesses are arranged along a circular path which is around a center of the fixing shaft; the disk is rotatable with respect to the seat by using at least one ball; the at least one ball is installed on a bottom side of the disk; a lower side of the ball exposes out from the bottom side of the disk and is located within one of the recesses of the disk; the disk is formed with an application unit; and when the disk rotates, the ball is driven by the disk to move to another recess to cause the disk is able of being fixed on various angles.

3. The multifunctional cooling and supporting apparatus for the tablet electronic device as claimed in claim 1, wherein material of the conducting plate is selected from at least one of metal, thermal conductive polymer, graphite and graphene.

4. The multifunctional cooling and supporting apparatus for the tablet electronic device as claimed in claim 1, wherein the heat conducting plate is installed in an inner side of the upper opening by a detachable way and the heat conducting plate seals the upper opening through a second waterproof annular strip; the second waterproof annular strip is installed between the heat conducting plate and the inner side of the upper opening; and the second waterproof annular strip surrounds the inner side of the upper opening and seals a gap between the heat conducting plate and the inner side of the upper opening.

5. The multifunctional cooling and supporting apparatus for the tablet electronic device as claimed in claim 1, wherein an inner side of the upper opening has a plurality of first buckles and the heat conducting plate has a plurality of second buckles to buckle the first buckles to fix the heat conducting plate to the inner side of the upper opening.

6. The multifunctional cooling and supporting apparatus for the tablet electronic device as claimed in claim 1, wherein an inner side of the upper opening has glue to bind the heat conducting plate; and a gap between the heat conducting plate and the inner side of the upper opening is sealed by the glue.

7. The multifunctional cooling and supporting apparatus for the tablet electronic device as claimed in claim 1, wherein the upper cover is assembled to the lower cover by means of screwing, buckling, or embedding.

8. The multifunctional cooling and supporting apparatus for the tablet electronic device as claimed in claim 1, wherein a first waterproof annular strip is installed between an inner side of the upper cover and an inner side of the lower cover; the first waterproof annular strip seals a gap between the inner side of the upper cover and the inner side of the lower cover; and the upper cover, the lower cover and the first waterproof annular strip form the waterproof structure of the protective case to seal the hollow space.

9. The multifunctional cooling and supporting apparatus for the tablet electronic device as claimed in claim 1, wherein the lower cover has a transparent area; a screen of the tablet electronic device faces the transparent area and the back end of the tablet electronic device faces the upper opening; the lower cover of the protective case has a lower opening which is sealed by a transparent plate; and the transparent plate forms the transparent area of the lower cover.

10. The multifunctional cooling and supporting apparatus for the tablet electronic device as claimed in claim 2, wherein the protective case further includes a connecting base installed on the outer side of the heat conducting plate by a plurality of second connecting components which passes through a plurality of first assembling holes of the connecting base and a plurality of second assembling holes of the heat conducting plate; a bottom of the seat is connected to the upper side of the protective case by a plurality of connecting units; and the connecting units pass through a plurality of retaining holes of the seat and the first assembling holes of the connecting base.

11. The multifunctional cooling and supporting apparatus for the tablet electronic device as claimed in claim 2, wherein the disk is formed with at least one installing hole which is opened at the bottom side of the disk; each of the at least one installing hole is installed with one of the at least one ball; the lower side of the ball exposes out from a lower opening of the installing hole; an upper side of each of the at least one ball is installed with a respective spring which is confined with the installing hole; the ball exposes out of the disk or reduces into the installing hole through elasticity of the spring; and a sealing unit is arranged at an upper side of the installing hole to seal the spring within the installing hole.

12. The multifunctional cooling and supporting apparatus for the tablet electronic device as claimed in claim 2, wherein the stand frame further includes a hand strap which is arranged across two sides of the disk by a detachable way; the two sides of the disk are formed with two via holes, respectively; a rib is formed between one of the two via holes and a respective one of the two sides of the disk; two ends of the hand strap are wound around the respective ribs; a middle part of the hand strap is arranged above the disk; the middle part of the hand strap has an arc portion; the hand strap serves to be held on a user's hand; and a space between the hand strap and the disk serves to receive a user's hand so that the hand strap winds around the user's hand.

13. The multifunctional cooling and supporting apparatus for the tablet electronic device as claimed in claim 2, wherein the application unit is a rotating frame; one end of the rotating frame is pivotally installed at a side of the disk;
wherein by rotating the rotating frame, the rotating frame serves to support the protective case to cause the protective case to stand; and
wherein by rotating the rotating frame, the rotating frame serves to hang the protective case on a specific location.

14. The multifunctional cooling and supporting apparatus for the tablet electronic device as claimed in claim 2, wherein the fixing shaft contains a rotatable shaft at a center portion of the seat and a fixing unit connected to an upper side of the rotatable shaft; a center of the rotatable shaft is formed with a locking hole; an upper side of the fixing unit is formed with an expansion portion and the disk is clamped between the expansion portion and the seat; a lower side of the fixing unit is locked to the locking hole of the rotatable shaft; the through hole contains an upper hole and a lower hole at a lower side of the upper hole; a cross section of upper hole is larger than that of the lower hole; and the expansion portion is embedded into the upper hole to resist against a bottom of the upper hole.

15. The multifunctional cooling and supporting apparatus for the tablet electronic device as claimed in claim 14, wherein a center of the fixing unit has a screw hole for screwing a supporting object; the supporting object contains a connecting magnetic surface; a center of the connecting magnetic surface has a screw rob which is movable by using a screw ring; by connecting the connecting magnetic surface and the outer surface of the fixing unit, and rotating the screw ring to cause the screw rob to screw into the screw hole of the fixing unit, the supporting object is installed on the protective case stably.
